(19) United States
(12) Patent Application Publication
(10) Pub. No.: US 2010/0218802 A1
(43) Pub. Date: Sep. 2, 2010

(54) JUNCTION BOX, SOLAR PANEL, CONTACT DEVICE, AND METHOD

(75) Inventor: Michael Quiter, Ebersberg (DE)

Correspondence Address: MAIER & MAIER, PLLC, 1000 DUKE STREET, ALEXANDRIA, VA, 22314, US

(73) Assignees: Yamaichi Electronics Co., Ltd., Tokyo (JP); Yamaichi Electronics Deutschland GmbH, Munich (DE)

(21) Appl. No.: 12/721,073

(22) Filed: Mar. 10, 2010

Related U.S. Application Data
(63) Continuation of application No. PCT/EP2008/007498, filed on Sep. 11, 2008.

(30) Foreign Application Priority Data
Sep. 11, 2007 (DE) 10 2007 043 178.5

(51) Int. Cl. H01L 31/042; H01R 13/60; H01R 43/00

(52) U.S. Cl. 136/244; 439/535; 29/857

(57) ABSTRACT

In summary, the present invention relates to a junction box for a conductor board, in particular for a solar module, comprising: a base carrier with at least one opening area, and at least one contact device, wherein the at least one contact device is arranged in the interior of the base carrier such that at least one electrical conductor is insertable into the junction box through the at least one opening area along an insertion direction and contactable with the at least one contact device, wherein the at least one contact device comprises at least one contact element with at least one resilient terminal contact spring and at least one terminal element, and wherein by application of a force parallel to a direction of force relative to the terminal element, the at least one terminal contact spring is resiliently displaceable such that the at least one electrical conductor is arrangeable at least partially between the at least one terminal element and the at least one terminal contact spring, as well as to a solar panel, a contact device and a method.

### CROSS REFERENCE TO RELATED APPLICATIONS

This is a continuation of the International Application No. PCT/EP2008/007498 filed on Sep. 11, 2008.

### BACKGROUND

1. Technical Field

The invention relates to a junction or connection box, a photovoltaic or solar panel, a contact device, and a method.

2. Related Art

Conventional solar or photovoltaic modules for generating electric energy from sunlight comprise one or more single solar or photovoltaic cells. Depending on the desired voltage and/or current to be provided by the solar module, the individual solar cells are connected in parallel and/or in series within the module and thus gathered in photovoltaic or solar cell groups. The solar cell groups are integrated in a flat solar module. The electrical terminals of the solar cell groups of the solar module are routed to the outside. In case of a partial decrease of the radiation intensity by sunlight onto individual solar cells or solar cell groups, for example by soiling or shading, the following effects may occur among others: (1) A (constant) decrease of the radiation intensity within the solar cell groups connected together leads to a reduced performance of the respective solar cell group. (2) If a solar cell within a solar cell group is partially shaded, this shaded solar cell acts as a blocking diode or resistor within the circuit of the solar cell group, which on the one hand may result in the entire solar cell group no longer being able to supply electric energy, and on the other hand in a damage of the shaded solar cell and thus to a permanent breakdown of the solar cell group. In any case, different voltages may be applied between the routed-out terminals of the solar cell group of a solar module, depending on the radiation intensity onto the individual solar cells. A connection in series of the solar cell groups by corresponding circuiting of the terminals routed to the outside analogously leads to the above-mentioned problems.

In order to avoid the problems related with the differing radiation intensity of the solar cells, conventional so-called bypass diodes are used, which are electrically connected in an anti-parallel manner with respect to the solar cell groups. These bypass diodes have the effect that the current flow through the solar module is led past solar cell groups that only supply low power, i.e. the terminals of this solar cell group of a solar module are short-circuited by the bypass diode and the corresponding cell group is bypassed thereby. Thus, such a solar cell group does no longer contribute to the overall performance of the solar module, but the overall current flow through the solar panel is substantially unobstructed and a damage of individual solar cell is avoided.

Therefore, in addition to the solar module, solar panels usually comprise an electrical junction or connection box with at least two contact devices and at least one bypass diode. The solar cells in a solar module are usually connected to each other by flat, thin conductor bands. These conductor bands are routed out of the solar module and manually contacted with an electrical terminal receptacle. The junction box of the solar panel therefore usually has an opening on the side facing the solar module, through which opening the conductor bands are routed through, bent manually and connected for example to connection terminals. Conventionally, the junction box is subsequently filled with an insulating resin in order to fixedly connect the conductor bands with each other and to insulate them from each other. The solar module provided with the junction box is referred to as photovoltaic or solar panel. An exemplary junction box is described in the German patent application with the application number DE 10 2005 025 976.

Due to the manual connecting, the assembly is cost and time-intensive. It is therefore an object of the invention to provide an electrical junction or connection box, a photovoltaic or solar panel, a contact device, and a method for automatically connecting the junction box, enabling a simple, reliable and cost-effective assembly.

The objects are solved by the independent claims. Preferred embodiments are subject of the dependent claims.

### SUMMARY

### Junction Box According to One Aspect

One aspect of the present invention relates to a junction or connection box for a circuit or conductor board, in particular for a photovoltaic or solar module, comprising:

a base carrier with at least one opening area, and

at least one contact device, wherein
the at least one contact device is arranged in the interior of the base carrier such that at least one electrical conductor is insertable into the junction box through the at least one opening area along an insertion direction and contactable with the at least one contact device, wherein
the at least one contact device comprises at least one contact element with at least one resilient terminal contact spring and at least one terminal element, and wherein
by application of a force parallel to a direction of force K relative to the terminal element, the at least one terminal contact spring is resiliently displaceable such that the at least one electrical conductor is arrangeable at least partially between the at least one terminal element and the at least one terminal contact spring.

### BRIEF DESCRIPTION OF THE DRAWINGS

Preferred embodiments of the present invention will exemplarily be described in the following on the basis of the accompanying drawings.

FIG. 1 is a perspective view of an embodiment of a solar panel with a junction box.

FIG. 2 is a view according to FIG. 1.

FIG. 3 is a perspective view of an embodiment of the interior of a junction box.

FIG. 4 is a perspective exploded view of an embodiment of a terminal device of a junction box.

FIG. 5 is a perspective view of an embodiment of the auxiliary means.

FIG. 6 is a sectional view of the contact devices.

### DESCRIPTION OF EXEMPLARY EMBODIMENTS

### Definition of Terms

The term “in the interior” as used in this application in particular describes a volume area for example surrounded by the housing of the junction box. In other words, the term “in the interior” describes the internal volume of the junction box. It is not necessary here that the junction box is closed. For example, the junction box may have a lid and the lid must not be arranged on or at the junction box. Nevertheless, the term “in the interior” describes the internal volume as if the lid was arranged. In other words, the term “in the interior” describes the internal volume of an ideally fully closed junction box. The contact device may also be arranged such that a part of the contact device projects out or is routed out of the junction box through a corresponding opening. However, as long as a part or area of the contact device, in particular the area in or on which the electrical conductor is arrangeable, is arranged within the internal volume of the junction box, this area is “in the interior” of the junction box. Thus, the term “in the interior” logically also includes e.g. “substantially in the interior” and also “at least partially in the interior”.

The term “direction of force” as defined by the invention describes a direction along which a force may be applied. For example, the direction of force K may be substantially perpendicular to a bottom surface or the base carrier of the junction box. The bottom surface is e.g. the surface that includes the opening areas and/or at or on which the contact device(s) is/are arranged. For example, the direction of force K may be substantially parallel to a surface of the conductor board at or on which the junction box is arranged. It is also possible that the direction of force K encloses an angle between approx. 85° and approx. 60°, in particular an angle between approx. 85° and approx. 65°, in particular an angle between approx. 75° and approx. 70°, with the reference plane, for example the bottom of the junction box and/or the surface of the conductor board. Particularly preferably, the direction of force K is oriented such that the terminal contact spring is displaceable or displaced relative to the terminal element upon application of a force. For example, the direction of force K points from the junction box toward the conductor board. A direction anti-parallel to the direction of force K for example points from the conductor board toward the junction box.

The “insertion direction” as defined by the present invention is e.g. a direction in which one or more electrical conductors are routed or routable into the junction box. For example, the insertion direction may be parallel to a longitudinal axis of one or all electrical conductors. The insertion direction may also be perpendicular to the surface of the conductor board. The insertion direction may also be perpendicular to the base carrier. In particular, the insertion direction may be perpendicular to the bottom of the junction box. For example, the insertion direction may be directed from the conductor board toward the junction box. In particular, the insertion direction may be determined by the longitudinal extension of one or more electrical conductors substantially extending perpendicular to the surface of the conductor board, wherein the insertion direction is directed substantially perpendicular to the base carrier and from the opening area of the base carrier into the interior of the junction box. By the insertion of the at least one electrical conductor, the at least one electrical conductor is contactable with the at least one contact device, i.e. a bending of the electrical conductor is advantageously not possible.

The term “position of rest” as defined by the present invention for example describes the state or position of one or more electrical components, in particular the contact device or components of the contact device. The contact device may e.g. have one or more receptacles into which external electrical conductors, for example an electrical conductor of the conductor board and/or an electrical conductor of a diode, are insertable. In the position of rest of the corresponding receptacle or the component comprising said receptacle, for example the corresponding external electrical conductor is not inserted into the receptacle and does not contact this receptacle electrically and/or or mechanically. The term “position of rest” as defined by the present invention in particular describes that position of e.g. the terminal contact spring, in which the terminal contact spring is when the junction box is not connected with the conductor board. In other words, in the position of rest of the terminal contact spring, the junction box is e.g. not mounted at or on the conductor board. In the position of rest, the electrical conductors are at least not yet inserted into the insertion area(s). In addition, an electrical and/or mechanical contact between the terminal contact spring and the terminal element may be present in the position of rest. In other words, the position of rest of the terminal contact spring corresponds to that position in which the terminal contact spring is when no external force, in particular no force in the direction of force K, is applied to the terminal contact spring. Furthermore, it is not necessary that the terminal contact spring contacts the terminal element in the position of rest. In this case, the position of rest is the position the terminal contact spring takes up in a substantially relaxed state when no force is applied.

The term “actuating position” as defined by the present invention describes for example the state or position of the above-mentioned electrical components, in particular the contact device or components of the contact device, such as the above-mentioned one or several receptacles. In contrast to the position of rest, a force is applied to one or more parts or the electrical components in the actuating position. In particular, it is possible in the actuating position that one or more electrical conductors are insertable or inserted into the receptacle(s). The term “actuating position” as defined by the present invention thus in particular describes a position in which the terminal contact spring and the terminal element are spaced from each other. For example, the actuating position may be achieved by applying a force in the direction of force K to the terminal contact spring. Due to the applied force, the terminal contact spring for example moves from the position of rest to the actuating position. Here, both a mechanical and/or an electrical contact between the terminal contact spring and the terminal element may be disconnected. However, the conductor may e.g. as well be arranged between the terminal contact spring and the terminal element, and the force along the direction of force K is no longer applied. Due to the spring force, the terminal contact spring presses the conductor against the terminal element. Also in this case, the terminal contact spring is in the actuating position, but contacts the terminal element only indirectly via the electrical conductor.

The term “contact” as defined by the present invention in particular includes electrical and/or mechanical contact.

The expression “arranged such that” includes, e.g. applied with respect to a component 1 and a component 2, that the component 1 is arranged at or on the other component 2, so that the component 1 and/or the component 2 serve(s) a predetermined purpose or perform(s) a predetermined method. This may in particular include that the component 1 and/or the component 2 exclusively serve(s) this purpose or perform(s) this method. Thus, the expression “arranged such that” includes that the system of component 1 and component 2 is structurally or physically adapted. In other words, the system in which the component 1 is arranged at or on component 2 such that a specific purpose is served or a specific method is performed may be distinguished from a system in which the component 1 is not arranged at or on the component 2 in such a manner. Likewise, with respect to a component 1, the expression “designed such that” includes that said component 1 serves a predetermined purpose or performs a predetermined method. This may include that the component 1 is structurally specially designed for this purpose and/or is specially arranged. In other words, a component 1 that is “designed such that” a specific purpose is served or a specific method is performed may be structurally or physically be distinguished from a component that is not designed in such a manner.

### Preferred Embodiments of the Junction Box

Preferably, the contact device is suitable or designed such that the force can be applied to the terminal contact spring by an auxiliary means. In particular, the terminal contact spring is arranged in the contact device such that the terminal contact spring can be accessed from outside the contact device at least in some areas in order to insert an auxiliary means at least into some areas of the contact device, which auxiliary means is capable of mechanically contacting the terminal contact spring in order to apply a force thereto.

Further preferably, the at least one terminal contact spring is formed resiliently such that when the applied force is missing, the at least one terminal contact spring fixes the electrical conductor arranged between the terminal contact spring and the terminal element and connects it with the contact device in an electrically conducting manner.

That means, the terminal contact spring has a sufficiently high spring constant or a sufficiently high modulus of elasticity in order to apply a reaction force that fixes the conductor, due to the geometric deflection by the electrical conductor arranged between the terminal contact spring and the terminal element.

In other words, it is advantageously possible to connect the junction box with the conductor board in a simple manner, wherein in particular an automatic arrangement of the junction box at or on the conductor board is possible. Due to the terminal contact spring being spaced from the terminal element for example by the auxiliary means, it is achieved that a clearance, in the following also referred to as insertion area, is created in the contact device, in particular in a contact area of the contact device. In this clearance or insertion area, at least one electrical conductor can be inserted or is insertable. Since a clearance is provided, it is advantageously not necessary that the conductor applies a force or that force is applied by means of the conductor in order to insert the conductor into the contact device and in particular into the contact area of the contact device. Rather, the conductor is insertable into the contact device substantially free of force. The term “free of force” as defined by the present invention describes that no force or a force about ½ of the force along the direction of force K, or a force about ¼, ⅛, 1/100, 1/1000 of the force along the direction of force K is applied to the at least one electrical conductor or is applied therewith.

Further preferably, the electrical conductor is fixed in the contact device due to the resilient terminal contact spring. Consequently, a time and cost-intensive filling of the junction box e.g. with a synthetic resin is avoided. Furthermore, two or more electrical conductors may be arranged in the junction box. In particular, two contact devices or more, e.g. four, six, eight, ten, twelve, etc., contact devices may be arranged in the junction box. If electrical conductors are connected with the respective contact devices and in particular fixed in the contact devices by means of the respective terminal contact springs and terminal elements, it is advantageously not necessary to electrically insulate the electrical conductors from each other in addition e.g. by filling with a synthetic resin. Thus, the junction box can be mounted to or on the conductor board, in particular automatically, in a simple and secure manner.

Preferably, an opening area is assigned to each contact device and each contact device surrounds the assigned opening area.

Further preferably, the junction box comprises four contact devices and four opening areas, wherein an opening area is assigned to each contact device and each contact device surrounds the assigned opening area.

In other words, the base carrier may have four or more openings, in particular six, eight, ten, twelve, etc., openings. The openings may e.g. be rectangular when viewed from above. In a three-dimensional space, the opening areas may e.g. also have the shape of a parallelepiped. Alternatively, the openings or opening areas may also be circular or oval when viewed from above. It is in particular possible for different opening areas to have different shapes. Each contact device preferably surrounds exactly one opening area or exactly one opening. In particular, each contact element and/or each contact area of every one of the contact devices preferably surrounds exactly one opening area. Alternatively or in addition, a contact device, in particular a contact element and/or a contact area, may also surround several opening areas or openings. Alternatively or in addition, several contact devices or several contact elements and/or several contact areas (of one or more contact devices) may together surround exactly one opening area. Here, it is also possible that the opening area is only surround partially.

Each contact area and/or each contact element of a contact device may also have several terminal contact springs and/or terminal elements. For example, the contact element may have two, three, four, etc., terminal contact springs and/or two, three, four, etc., terminal elements. Furthermore, the at least one terminal contact spring and the at least one contact element of every one of the contact elements may be displaceable relative to each other. In other words, one or more terminal elements may be designed in a resilient fashion. The force in the direction of force K may e.g. be applied or be applicable to the at least one terminal contact spring and/or the at least one terminal element. In particular, if the terminal element is fixed, the terminal contact spring can move away from the terminal element, or if the terminal contact spring is fixed, the terminal element can move away from the terminal contact spring, or neither the terminal contact spring nor the terminal element are fixed and the terminal contact spring and the terminal element move away from each other by a mutual movement.

Further preferably, in a position of rest, the at least one terminal contact spring contacts the at least one terminal element at least partially in a mechanical manner.

Further preferably, if a force is applied along the direction of force K, the at least one terminal contact spring is spaced from the at least one terminal element such that an insertion area is formed between the at least one terminal contact spring and the at least one terminal element.

Further preferably, the insertion area is arranged above the at least one opening area.

Particularly preferably, each insertion area is arranged above an opening area. The insertion area is preferably formed to receive at least one conductor.

Preferably, the at least one contact device is arranged relative to the at least one opening area such that the direction of force K and the insertion direction are opposed.

In other words, the direction of force K and the insertion direction are preferably anti-parallel.

Preferably, the insertion area is designed such that the at least one electrical conductor is insertable into the insertion area through the opening area substantially free of force.

Particularly preferably, the terminal contact spring is a leaf spring.

Further preferably, the terminal contact spring has a fixing area with which the terminal contact spring is fixed to or on the contact device, and

the terminal contact spring has an area that is proximal relative to the fixing area and an area that is distal relative to the fixing area, wherein
the proximal area is designed such that when a force is applied to the proximal area parallel to the direction of force K, the terminal contact spring de-contacts the terminal element, and when a force is applied to the distal area anti-parallel to the direction of force K, the terminal contact spring contacts the terminal element.

The contact may be mechanical and/or electrical.

Preferably, in the proximal area, the terminal contact spring has a bend of approx. 0° to approx. 180°, preferably approx. 10° to approx. 170°, particularly preferably approx. 20° to approx. 160°.

Further preferably, the contact element is formed monolithically or in one piece. In particular, the contact element may have a cross-section identical to that of the opening area surrounded by the contact element. The contact element may be formed of a metal or a metal alloy.

In other words, the present invention may relate to modules, in particular for photovoltaic or solar modules, preferably comprising: a base carrier, at least one contact device, which in the arrangement position is attached in an upper area of the base carrier, i.e. the area facing the interior of the junction box, and at least one outside terminal area, wherein the base carrier has at least one opening area for routing electrical lines through the base carrier, each contact device has a contact element, further preferably comprising a short-circuit area and a terminal area, a contact element housing and a terminal contact spring, wherein the terminal contact spring in the position of rest contacts the terminal area, in particular the terminal element of the contact element, preferably fully, the terminal contact spring in the actuating position does not contact the terminal area of the contact element, in particular the terminal element of the contact element, at least in some areas, so that an insertion area is located or defined between the terminal contact spring and the contact element and a terminal contact spring can be brought from the position of rest to the actuating position by a force acting on the terminal contact spring from above, and wherein the insertion area is at least in some areas located above an opening area of the base carrier, so that an electrical line routed through the base carrier in the opening area is arrangeable at a terminal contact spring being in an actuating position substantially without applying an insertion force in the insertion area between the terminal area, in particular terminal element and terminal contact spring.

Preferably, the junction box has at least one housing comprising at least one base carrier. The junction box may be arrangeable on the terminal side of a photovoltaic module as a preferred circuit or conductor board and may additionally be brought to an arrangement position. In the arrangement position, the side of the base carrier designed to be arranged at or on the photovoltaic module faces downward, i.e. in the direction of the center of the earth, wherein the photovoltaic module in the arrangement position is substantially parallel to a geoid, i.e. parallel to the normal-zero equipotential surface of the Earth's gravitational field with respect to which the force of gravity is always perpendicular. This arrangement may also be referred to as “horizontal”. The side of the junction box or the housing of the junction box, which is designed to be arranged in a manner facing away from the photovoltaic module and facing toward the interior of the junction boxes, may accordingly be referred to as “top”. Advantageously, the terminal contact spring can be brought to the actuating position by a force acting from above, i.e. a force acting from the side of the junction box facing away from the photovoltaic module and thus being easily accessible. According to this description, the force is substantially in the direction of force K. In the arrangement position, the direction of force K is preferably substantially parallel to a vertical direction in the terrestrial reference system. Advantageously, the electrical lines of the photovoltaic module as preferred electrical conductors may be inserted into the insertion area of the contact device substantially without application of an insertion force if the terminal contact spring is in the actuating position. According to this description, the insertion force is substantially parallel to the insertion direction. In the arrangement position, the insertion direction is substantially parallel to a vertical direction in the terrestrial reference system. In other words, the insertion direction is preferably substantially opposite to the direction of force K.

Based on the preceding description, it is in particular not necessary that the electrical lines have to apply a force themselves directly and/or indirectly upon insertion into the insertion area and merely very little force is required. This is advantageous in that the electrical lines are usually designed as thin conductor bands. These thin conductor bands can be easily deformed and/or bent and can thus correspondingly only apply low forces or these conductors may only be loaded with low forces, without a deformation of the conductors, for example. Furthermore, the insertion of the electrical lines does substantially not require any further manual work or manual procedures. Therefore, it is advantageously possible that automatic insertion equipment takes over this job. By an external application of force to bring the terminal contact spring to the actuating position, advantageously greater forces can be applied than it would be possible by the electrical lines themselves, in order to overcome the resilient force of the terminal contact spring. Therefore, springs, in particular terminal contact springs, may advantageously used, which have an increased or very high resilient force, whereby a secure contacting is established or fixed in a particularly advantageous manner, and the junction box is securely and fixedly connectable with the electrical conductors of the photovoltaic module. Preferably, the resilient force is approx. 6 to approx. 30 N, particularly preferably approx. 10 to approx. 20 N.

Due to the preferred design of the body of the terminal contact spring substantially as a leaf spring, the terminal contact spring can advantageously be produced in a particularly simple and cost-effective manner.

Preferably, the terminal contact spring, with an end distal with respect to a fixing area of the terminal contact spring, contacts an area (as a preferred terminal element) of the terminal area of the contact element, which lies opposite and below thereto, so that a force acting on the terminal contact spring from above, i.e. in the direction of force K, causes a de-contacting of the distal end of the terminal contact spring from the terminal area of the contact element, and that a force acting on the terminal contact spring from below, i.e. opposite to the direction of force K, causes the distal end of the terminal contact spring to be pressed against the terminal area of the contact element.

In other words, the terminal area of the contact element preferably has a terminal contact abutment area. Furthermore, the terminal contact spring preferably has a fixing area, a terminal contact and a leaf spring area. The fixing area is e.g. designed to fix the terminal contact spring to or on the terminal area of the contact element. The terminal contact may be designed to contact the terminal contact abutment area of the terminal area at least in some areas in the position of rest of the terminal contact spring.

Preferably, the leaf spring area is arranged between the fixing area and the terminal contact. Further preferably, the terminal area is e.g. designed as a hollow profile and the terminal contact spring is fixed in the interior of the hollow profile with the fixing area thereof. Moreover, preferably, the area of the leaf spring area proximal to the fixing area is designed in a curved fashion such that the terminal contact arranged at the distal end of the leaf spring area contacts the terminal contact abutment area of the terminal area at a point arranged below and opposite relative to the fixing area. Particularly preferably, the curved area is designed resiliently, i.e. it can be elastically and/or plastically deformed such that it substantially returns to its original position or shape after action of a deforming force. The original position or shape is that shape the curved area assumes for example in the position of rest of the terminal contact spring, i.e. in the position or state in which the junction box is not connected with the conductor board. In particular, this is the shape or position the curved area assumes if no electrical conductor is inserted in the insertion area and/or no force (in the direction of force K) is applied to the terminal contact spring.

As a result, a force acting on the leaf spring area of the terminal contact spring from above causes a de-contacting of the distal end, with respect to the fixing area, of the terminal contact spring from the terminal area of the contact element, i.e. the terminal contact from the terminal contact abutment area, as a preferred terminal element.

Preferably, the contact element housing is formed monolithically or in one piece, in particular of a polymer or an electrically non-conducting plastic.

Preferably, the contact element has a short-circuit contact spring. Particularly preferably, the contact element comprises at least two short-circuit contact spring receptacles or seats in which the short-circuit contact spring can engage in at least some areas. Further preferably, the contact element has a short-circuit contact abutment area.

Preferably, in the position of rest, the short-circuit contact spring contacts the short-circuit area of the contact element in the short-circuit contact abutment area.

Preferably, after insertion of a terminal portion of an electrical component, for example a diode, the short-circuit contact spring is brought from the position of rest of the short-circuit contact spring to an actuating position of the short-circuit contact spring, and the short-circuit contact spring contacts the short-circuit area of the contact element in the short-circuit contact abutment area at least in some areas.

Preferably, the short-circuit contact spring is designed monolithically or in one piece. Particularly preferably, the short-circuit contact spring is produced of metal.

Preferably, the junction box has at least one outside terminal area having at least one reverse polarity-protected, multi-polar jack with male or plug-like and/or female or socket-like contacts.

Preferably, the terminal area has at least one male or plug-like and/or at least one female or socket-like coaxial jack.

### Solar Panel According to One Aspect

A further aspect of the present invention relates to a photovoltaic or solar panel, comprising:

at least one substantially plate-shaped photovoltaic or solar module, and

at least one junction box according to the invention, wherein

the solar module comprises at least two electrical conductors, and the at least two electrical conductors each project through an opening area of the junction box and are each connected with a contact device of the junction box. The connection is preferably electrical and mechanical.

In other words, the solar panel may comprise: a photovoltaic or solar module having a substantially plate-shaped body with at least one voltage-generating photovoltaic or solar cell, at least two conductor bands connected with the at least one solar cell, which conductor bands are routed out of a solar cell at or on a surface thereof and are substantially parallel thereto, and at least one junction box according to the invention. Preferably, the junction box may have: a base carrier facing the module, at least two contact devices attached in an upper area of the base carrier, i.e. the area facing away from the module, and at least one terminal area, wherein the base carrier has at least one opening area for routing electrical lines through the base carrier, each contact device has a contact element, further comprising a short-circuit area and a terminal area, a contact element housing and a terminal contact spring, wherein the terminal contact spring in the position of rest of the terminal contact spring fully contacts the terminal area, the terminal contact spring in the actuating position of the terminal contact spring does not contact the terminal area of the contact element at least in some areas, so that an insertion area is located or defined between the terminal contact spring and the terminal area and the terminal contact spring can brought from the position of rest to the actuating position by a force acting on the terminal contact spring from above, and wherein the insertion area is at least in some areas located above an opening area of the base carrier, so that an electrical conductor routed through the base carrier in the opening area is arrangeable at a terminal contact spring being in an actuating position substantially without applying an insertion force in the insertion area between a terminal element (in the terminal area) and the terminal contact spring.

Since the conductors routed out of the solar module are not subject to mechanical stress within the solar panel, they may be designed in a thin fashion and do advantageously not require mechanical reinforcement.

### Contact Device for Arrangement in a Junction Box According to One Aspect

A further aspect of the present invention relates to a contact device for arrangement in a junction box, wherein

the contact device is arrangeable in the interior of the junction box such that at least one electrical conductor is insertable into the junction box through an opening area along an insertion direction and contactable with the at least one contact device, wherein
the contact device comprises at least one contact element with at least one resilient terminal contact spring and at least one terminal element, and wherein
by application of a force parallel to a direction of force K relative to the terminal element, the terminal contact spring is resiliently displaceable such that the at least one electrical conductor is arrangeable at least partially between the at least one terminal element and the at least one terminal contact spring.

### Method for Automatic Connection of a Junction Box According to One Aspect

A further aspect of the present invention relates to a method for automatically connecting a junction box with a circuit or conductor board, in particular a photovoltaic or solar module, with the steps:
providing the junction box in particular according to the invention by means of a gripping means, wherein the junction box comprises at least one opening area and at least one contact device,
at least partially inserting an auxiliary means into the at least one contact device such that a terminal contact spring is resiliently displaced by means of the auxiliary means and an insertion area is formed in the contact device,
activating an adhesive at or on the junction box and/or at or on the conductor board,
arranging the junction box at or on a face of the conductor board such that at least one electrical conductor is inserted into the insertion area of the contact device through at least one opening area of the junction box, and the junction box is fixed at or on the conductor board by means of the adhesive,
removing the auxiliary means so that the terminal contact spring is returned at least partially and a connection between the contact device and the electrical conductor is established or fixed,
removing the gripping means.

The gripping means for gripping the junction box may in particular be pliers-shaped and/or be a vacuum-operated device according to the invention or comprise such a device. The auxiliary means may be a device according to the invention or comprise such a device, and may in particular comprise a number of opening fingers equal to the number of contact devices, so that each opening finger applies a force to one terminal contact spring of a contact device.

The activation of the adhesive, which may in particular be a gluing agent or glue, for example comprises applying, in particular spraying, a deformable, particularly liquid glue to or onto the bottom side of the junction box, in particular to or onto a contact surface of the junction box with which the junction box contacts the conductor board. For example, the glue may cover the contact surface entirely. It is also possible that the glue is merely applied at discrete points to or onto the contact surface. In other words, the adhesive may comprise a liquid and/or a solid glue. In particular, the adhesive may be similar or identical with a double-sided adhesive tape.

Furthermore, the activation may comprise that the glue is given its gluing or adhesive property. The glue may e.g. be treated with heat and/or light, such as with UV light. The above description applies analogously if the glue is located at or on the surface, in particular the contact surface of the conductor board. The glue may e.g. be so-called two-component adhesive, wherein one component is located at or on the junction box and a further component at or on the conductor board. The activation may thus comprise that the two components are brought into contact with each other. Here, for example a surface of the conductor board may comprise glue, which is larger than the contact surface with the junction box.

Alternatively or in addition, the activation of the glue may also comprise that a protective foil is removed from the glue.

### Preferred Embodiments of the Method

Preferably, the electrical conductor is fixed in the insertion area in the electrical contact device and connected with the electrical contact device in a conducting manner by means of the terminal contact spring.

Further preferably, the at least one electrical conductor is inserted into the insertion area of the contact device substantially free of force.

Preferably, a cover device is arranged at or on the junction box such that the junction box is substantially fully closed.

Logically, the present invention may also comprise a corresponding use of a contact device and/or a corresponding use of a junction box for connection with a circuit or conductor board, wherein the above description applies analogously.

In other words, a method for attaching a junction box to a solar or photovoltaic module as a preferred circuit or conductor board may comprise the following steps:

(A) providing a substantially plate-shaped solar or photovoltaic module with at least two conductor bands, which are routed out of a solar or photovoltaic cell at or on a surface thereof and are substantially parallel thereto.

Preferably, step (A) may further comprise erecting the conductor bands into a perpendicular position.

(B) Providing a junction box that may have: a base carrier facing the module, at least two contact devices attached in an upper area of the base carrier, i.e. the area facing away from the module, and at least one terminal area, wherein the base carrier has at least one opening area for routing electrical lines through the base carrier, wherein each contact device has a contact element, further comprising a short-circuit area and a terminal area, a contact element housing and a terminal contact spring, wherein the terminal contact spring in the position of rest can fully contact the terminal area of the contact element, the terminal contact spring in the actuating position cannot contact the terminal area of the contact element at least in some areas, so that an insertion area is located or defined between the terminal contact spring and the terminal area and the terminal contact spring can be brought from the position of rest to the actuating position by a force acting on the terminal contact spring from above, and wherein the insertion area can at least in some areas be located above an opening area of the base carrier, so that an electrical conductor routed through the base carrier in the opening area is arrangeable at a terminal contact spring being in an actuating position substantially without applying an insertion force in the insertion area between the terminal area and the terminal contact spring.
(C) Inserting at least one auxiliary means into the contact element from above in order to bring the terminal contact springs to an actuating position.
(D) Applying a glue to or onto the lower side of the base carrier and/or to or onto a surface of the solar module.
(E) Positioning the junction box above the solar module so that the insertion area is located above the substantially perpendicular conductor bands.
(F) Lowering the junction box so that the glue comes into contact with the surface of the solar module and the conductor bands are arranged in the insertion area.
(G) Removing the auxiliary means so that the terminal contact springs are allowed to move toward the position of rest and the conductor bands are thereby clamped between terminal contact springs and the terminal areas of the contact elements.

In particular the above-mentioned steps (C), (D) and (E) may be performed in an arbitrary order.

Preferably, the auxiliary means may be part of an automatic insertion equipment tool, so that the above-described steps may advantageously at least partially be performed in an automated manner. Advantageously, the conductor paths routed out of the solar module are substantially not subjected to mechanical stress, so that a reduced reject rate due to damaged conductor paths is achieved. In particular, the junction box and the solar module can be very quickly, in particular immediately, be connected with each other by the adhesive, which is preferably applied before the assembly, upon contact of the junction box with the solar module, so that the production time per solar panel decreases. Thereby, the solar panel can advantageously be produced in a more cost-effective manner and with improved quality by means of the above-described method.

Preferably, the above method comprises, in a further step (H), closing the junction box by a lid. This closure may e.g. be substantially fluidtight, in particular watertight and/or airtight.

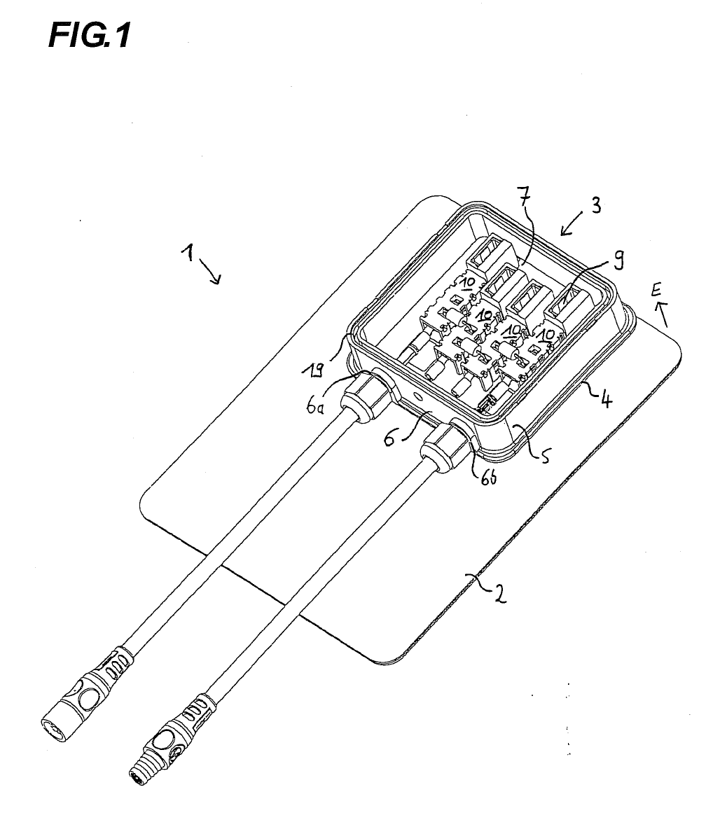

FIG. 1 shows a perspective view of an embodiment of a solar or photovoltaic panel 1 with a plate-shaped solar or photovoltaic module 2, wherein at least one voltage-generating solar or photovoltaic cell is arranged on a radiation side of the solar module 2, the electrical lines 9 of the solar cell being routed out of the solar module 2 in the form of conductor bands on the terminal side opposite to the radiation side. However, it is also possible to route out the electrical lines on the radiation side.

A junction box 3 is arranged at or on the terminal side of the solar module 2 at or on the same. The junction box 3 has a housing, which comprises a base carrier 4, a wall 5, an outside terminal area 6, an opening area 7 and a lid (not shown). The base carrier 4 is arranged on the side of the junction box facing the solar module 2, i.e. at the bottom. The side of the junction box facing away from the solar module is accordingly referred to as “top”. The lid (not shown) is arranged on this side in order to close the junction box. The base carrier 4 preferably serves to fix the junction box 3 on the terminal side of the solar module 2. The base carrier 4 has an opening area 7 for routing through the electrical lines 9 of the solar module 2. Preferably, in this embodiment, each of the electrical lines 9 is routed through an opening area 7 assigned to this line through the base carrier along an insertion direction E, from bottom to top, wherein each opening area 7 is tapered from the bottom to the top, so that advantageously the insertion is facilitated. In the embodiment shown in FIG. 1, four opening areas 7 are provided, and through each opening area 7 one conductor 9 is routed through.

The wall 5 of the base carrier 4 substantially extends perpendicular to the base carrier 4. Preferably, in an area of the wall 5 there is arranged an outside terminal area 6, which in this embodiment has a coaxial plug 6a and a coaxial socket 6b each, in order to electrically connect the solar panel 1 to an external device. In other words, the wall 5 comprises two openings that allow the coaxial plug 6a and the coaxial socket 6b to each be in electrical contact with a contact device 10 in the interior of the junction box. Moreover, at its upper edge, the wall 5 preferably has a groove 19 in at least some areas, in which groove a seal may preferably be arranged, so that the junction box 3 can be closed by the lid in particular in a fluidtight, particularly preferably watertight, manner. Likewise, the openings in the outside terminal area may be closed in a fluidtight manner.

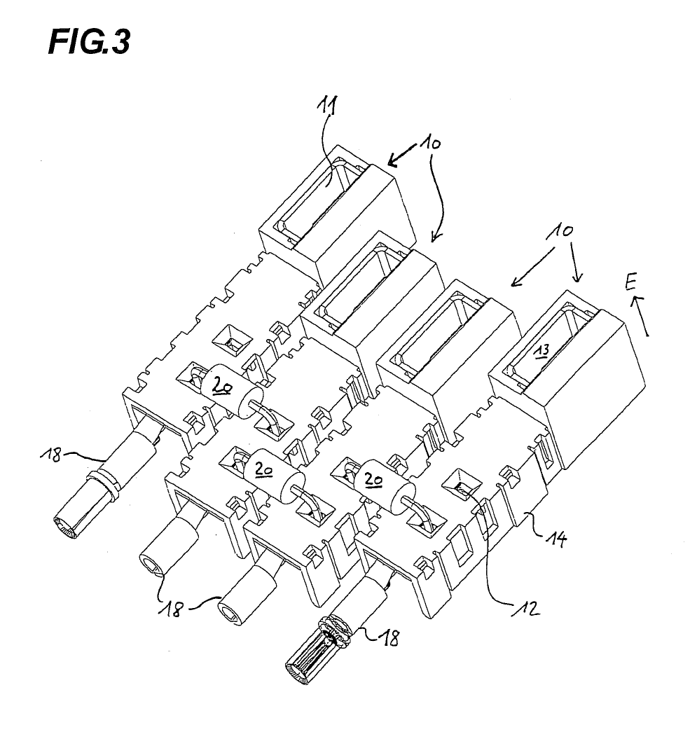

In this embodiment, four contact devices 10 are attached to the base carrier 4, which in the assembled state of the junction box, i.e. substantially in the actuating position of the terminal contact spring (shown in FIG. 3), contact the electrical lines 9 of the solar module 2, here in the form of conductor bands.

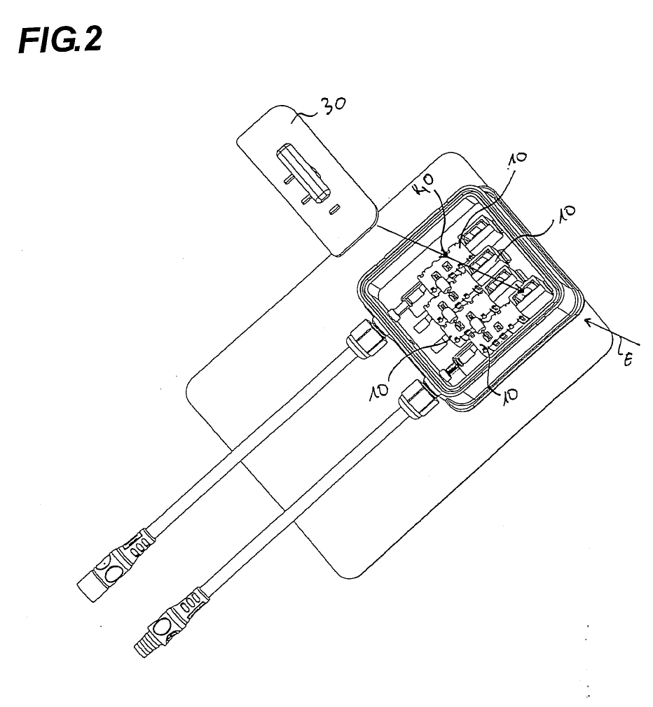

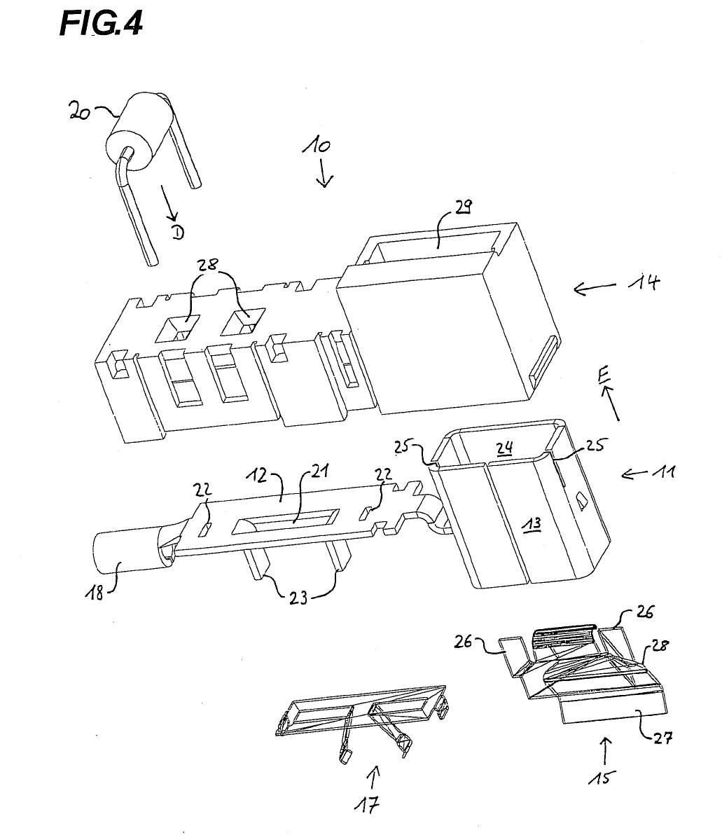

FIG. 2 shows a view according to FIG. 1, however with an auxiliary means 30 being illustrated. The auxiliary means has not yet been engaged or is no longer engaged with the contact devices 10. Furthermore, FIG. 2 shows the opening direction O along which the auxiliary means 30 may be moved toward the junction box in order to apply a force to the corresponding terminal contact springs (shown in FIG. 4) along the direction of force K. In addition, the insertion direction E is shown along which the conductors 9 can be inserted into the opening areas 7.

FIG. 3 shows a perspective view of the interior of the junction box 3, comprising four contact devices 10. Each contact device 10 has an electrically insulating contact element housing 14 and an electrically conductive contact element 11 that in turn comprises a short-circuit area 12 and a terminal area 13, which are electrically connected with each other by the electrically conductive body of the contact element 11. Arranged at or on the terminal area 13 are the electrical lines 9 (not shown) of the solar module 2 in the assembled state. The terminal area 13 is entirely arranged in the interior of the junction box 3.

The terminal areas 13 of two adjacent contact devices 10 are electrically connected with each other via the connected solar cell group. The short-circuit areas 12 of two adjacent contact devices 10 are electrically connected with each other by bypass diodes 20 such that the blocking direction of the bypass diodes 20 is anti-parallel to the flow direction of the current, which flows between the adjacent contact devices 10 via the solar cell group. If, for example, the electrical connection passing via the solar cell group has a resistance due to a shading such that the voltage drop exceeds a predetermined threshold, the voltage drop between the terminal areas of the corresponding adjacent contact devices 10 also exceeds a threshold value independent thereof. If the predetermined threshold is exceeded, the corresponding bypass diode looses its blocking effect and establishes a short-circuit between the adjacent contact devices 10. Preferably, the overall current of the solar panel does thus not flow through the bridged solar cell group, whereby neither electrical performance losses due to the increased resistance of the solar cell group nor a damaging of the solar cell group, for example caused by heating due to the electrical performance loss, occur. Instead, the electric current flows through the short-circuit areas 12.

FIG. 4 shows a perspective exploded view of the embodiment of the contact device 10 of the junction box 3. In this embodiment, each contact device 10 has a short-circuit contact spring 17 and a terminal contact spring 15 in addition to the contact element housing 14 and the contact element 11.

Preferably, the contact element 11 is integrally formed of metal and comprises a socket area 18 in addition to the short-circuit area 12 and the terminal area 13. These areas are electrically connected with each other by the metallic body of the contact element 11.

In this embodiment, the short-circuit area 12 of the contact element 11 is formed as a substantially rectangular opening 21 in the contact element 11, wherein the short-circuit area 12 extends in a short-circuit contact abutment area 23 on both short sides of the opening 21 downward along a diode insertion direction D of a bypass diode 20 and substantially perpendicular to the surface of the opening 21. Preferably, in the short-circuit area 12 and spaced from the opening 21 are formed at least two short-circuit contact spring receptacles 22 in which the short-circuit contact spring 17 can engage at least in some areas. The diode insertion direction D may e.g. be substantially perpendicular to the base body 4. The diode insertion direction D may in particular be parallel to the direction of force K.

The short-circuit contact spring 17 is preferably formed monolithically or in one piece and contacts in a position of rest of the short-circuit contact spring 17 the short-circuit contact abutment area 23 at least in some areas. By insertion of for example the bypass diode 20, the short-circuit contact spring 17 changes to an actuating position, so that the short-circuit contact spring 17 does not contact the short-circuit contact abutment area 23 in some areas. Here, the terminal area of the bypass diode 20 is located between the short-circuit contact spring 17 and the short-circuit contact abutment area 23 and clamped there, in particular releasably fixed, by means of a resilient force of the short-circuit contact spring 17.

In this embodiment, the terminal area 13 of the contact element 11 is formed substantially as a hollow profile, in particular with a substantially rectangular cross-section in the horizontal sectional plane and/or substantially rectangular cross-section in the substantially vertical sectional plane. Preferably, a terminal contact abutment area 24, substantially planar in at least some areas, as the preferred terminal element 24 is arranged such that it extends along an insertion direction E. The substantially planar terminal contact abutment area 24 is formed such that it contacts a conductor band 9 (not shown) extending along the insertion direction E. The terminal area 13 preferably has two slits 25 in which the terminal contact spring 15 can engage in at least some areas. In particular, the terminal contact abutment area 24 and the terminal contact spring 15 are formed such that when the conductor 9 is arranged in the insertion area 16 in the actuating position, but without any force applied, the electrical conductor is electrically connected with the terminal contact abutment area 24 and/or the terminal contact spring 15 due to the spring force of the terminal contact spring 15. Furthermore, due to the spring force, the electrical conductor 9 is fixed, in particular clamped, between the terminal contact spring 15 and the terminal contact abutment area 24. The fixation may be releasable, i.e. by insertion of the auxiliary means and application of force in the direction of force K, the terminal contact spring 15 can be displaced that much that the electrical conductor 9 can be removed from the insertion area 16. Thus, the junction box is reusable. Alternatively or in addition, the terminal contact spring 15 may also be designed such that by application of a correspondingly great force to the junction box 3 opposite to the direction of force K and/or the solar module 2 in the direction of force K, the junction box 3 can be removed from the solar module 2 and the connection between the conductor 9 and the contact device 10 is releasable.

The terminal contact spring 15 has a fixing area 26, a terminal contact 27 and a leaf spring area 28. The fixing area 26 is designed so as to engage the slits 25 in at least some areas and to fix the terminal contact spring 15 at or on the terminal area 13 of the contact element 11. The terminal contact 27 is formed in a planar fashion in at least some areas in order to contact the terminal contact abutment area 24 in at least some areas in a position of rest of the terminal contact spring 13 in particular in a positive manner. The leaf spring area 28 substantially forming the body of the terminal contact spring 15 is preferably formed substantially as a leaf spring. Further preferably, an area of the leaf spring area 28 that is proximal to the fixing area 26 is formed in a curved fashion. The curvature is designed such that the terminal contact 27 arranged at a distal end of the leaf spring area 28 contacts a terminal contact abutment area 24, wherein the terminal contact abutment area 24 is arranged below the fixing area 26 or the slits 25, i.e. opposite to the insertion direction E, and lies opposite thereto. From this arrangement, it results that a force acting on the leaf spring area 28 of the terminal contact spring 15 from above, i.e. opposite to the insertion direction E (and thus opposite to the direction of force K) causes a de-contacting of the distal end, with respect to the fixing area 26, of the terminal contact spring from the terminal area of the contact element. In other words, the terminal contact 27 is removed or released from the terminal contact abutment area 24. However, a force acting on the leaf spring area 28 of the terminal contact spring 15 from below, i.e. in the insertion direction E, causes a pressing-against or securing of the electrical contact.

In this embodiment, the socket area 18 of the contact element 11 is formed as a substantially cylindrical area.

The contact element housing 14 is preferably formed of an electrically insulating material, for example a polymer or rubber. The contact element housing 14 has at least one terminal opening 28 arranged such that the terminal area of the bypass diode 20 can be inserted into the short-circuit area 12 through the terminal opening 28. Preferably, this terminal opening is conical, i.e. tapered along the diode insertion direction D of the bypass diode 20. The contact element housing 14 has a terminal area opening 29 substantially arranged above the terminal area 13 and through which a force can be applied to the leaf spring area 28 of the terminal contact spring 15, for example by means of an auxiliary means 30 (shown in FIG. 2).

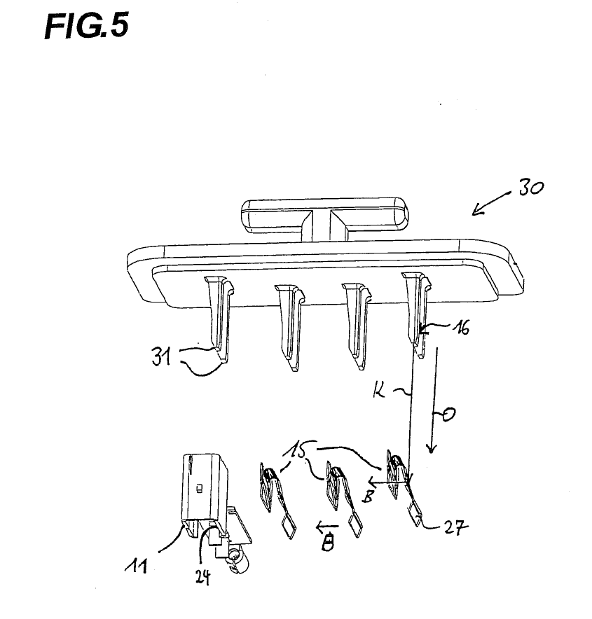

FIG. 5 shows a perspective view of the auxiliary means 30 or opening tool 30 or opening auxiliary means 30 as a preferred auxiliary means and the corresponding arrangement of the terminal contact springs 15, as they are arranged in the junction box. Since the opening auxiliary means 30 has not yet been inserted into the contact elements 11, the terminal contact springs 15 are in the position of rest, i.e. the terminal contact 27 of the terminal contact springs 15 contacts the terminal contact abutment area 24 of the terminal area 13 of the contact element 11.

The opening auxiliary means 30 comprises a pair of opening fingers 31 preferably for each terminal contact spring 15 to be opened, which fingers have a conical design preferably in the opening direction O. In FIG. 5, the opening direction O equals the direction of force K. Also, one opening finger may be provided for each terminal contact spring 15. The opening fingers 31 of a pair are preferably arranged in a mutually spaced manner. The opening auxiliary means 30 is insertable into the contact elements along the opening direction O. By the insertion of the opening auxiliary means 30, the terminal contact 27 of at least one terminal contact spring 15 is brought from the position of rest to an actuating position, wherein the terminal contact 27 displaces along a movement direction F of the terminal contact spring 15. In other words, by the insertion of the auxiliary means 30 along the opening direction O, a force is applied to the terminal contact spring 15 in the direction of force K. In the actuating position, the terminal contact 27 of the terminal contact spring 15 is spaced from the terminal contact abutment area 24. The terminal contact 27 in the actuating position, the terminal contact abutment area 24 and the opening fingers 31 surround an insertion area 16. The insertion area 16 is at least in some areas arranged above the opening area 7 of the base carrier 4, so that the electrical conductor 9 routed through the opening area 7 is arrangeable in the insertion area 16 substantially without application of an insertion force. In FIG. 5, the insertion area 16 is illustrated with respect to the opening fingers 31. However, FIG. 5 is an exploded view, so that the insertion area 16 is positioned within the contact element 11 by means of the opening fingers 31 if the opening fingers 31 are arranged in the contact element 11.

After removal of the opening auxiliary means 30, the terminal contact 27 displaces opposite to the movement direction B of the terminal contact spring 15 back toward its position of rest. This position of rest is substantially not reached, since the electrical line 9 is arranged between the terminal contact 27 and the terminal contact abutment area 24 and clamped tightly by the resilient force of the terminal contact spring 15. In other words, due to the spring force of the terminal contact spring 15, the terminal contact 27 presses the electrical conductor 9, which is arranged in the insertion area 16, against the terminal contact abutment area 24, so that an electrical contact between the terminal area and the electrical conductor 9 is established or fixed.

In other words, for example the opening auxiliary means 30 and in particular the opening fingers 31 are moved along the opening direction O and also along the direction of force K toward the terminal contact springs 15. Thus, the opening fingers press on the terminal contact springs 15 along the direction of force K. As a result, the terminal contact springs 15 are moved along the movement direction B. Put differently, a force is applied to the opening auxiliary means 30 along the direction of force K. This force may be applied to the opening means 30 manually and/or by means of a machine. The force is transmitted to the terminal contact springs 15 by means of the opening fingers 31. In a vectorial representation of the force, a force is applied to the terminal contact springs 15 along the direction of force K. However, since the terminal contact springs 15 are fixed to or on the contact element, a force acts on the terminal contact springs 15 along the movement direction B, which is why the terminal contact springs 15 are deformed and in particular the terminal contacts 27 are moved or displaced along the movement direction B. The movement direction B is preferably perpendicular to the direction of force K. However, the movement direction B and the direction of force K may also have different angles with respect to each other, preferably between approx. 70° and approx. 100°, particularly preferably between approx. 80° and approx. 100°.

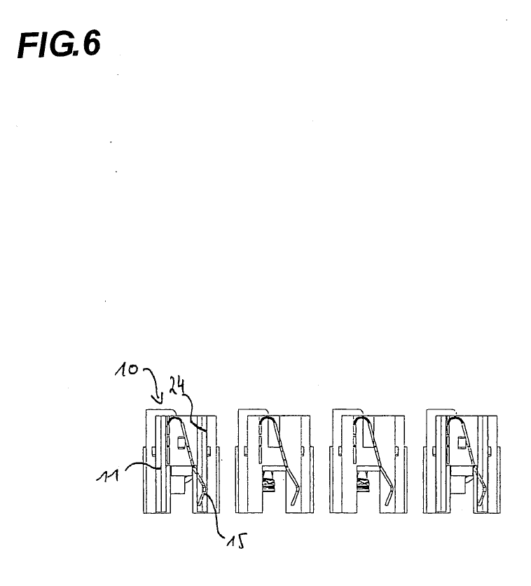

FIG. 6 shows a sectional view through four contact devices 10, with a contact element 11, a terminal contact spring 15 and a terminal element 24 each. The terminal contact springs are in a position of rest.

The present invention is not limited to the above-described exemplary embodiments. Instead, individual elements and/or features of each described aspect and/or of each described embodiment may be combined with individual elements and/or features of the further aspects and/or further embodiments in an arbitrary manner and thus form further aspects and/or embodiments.

This application is based upon and claims the benefit of priority from the prior German patent application No. DE 10 2007 043 178.5, filed on Sep. 11, 2007; the entire contents of which is incorporated herein by reference.

What is claimed is:

1. A junction box for a conductor board, in particular for a solar module, comprising:
a base carrier with at least one opening area, and
at least one contact device, wherein
the at least one contact device is arranged in the interior of the base carrier such that at least one electrical conductor is insertable into the junction box through the at least one opening area along an insertion direction and contactable with the at least one contact device, wherein
the at least one contact device comprises at least one contact element with at least one resilient terminal contact spring and at least one terminal element, and wherein
by application of a force parallel to a direction of force relative to the terminal element, the at least one terminal contact spring is resiliently displaceable such that the at least one electrical conductor is arrangeable at least partially between the at least one terminal element and the at least one terminal contact spring.

2. The junction box according to claim 1, wherein the contact device is suitable or designed such that the force can be applied to the terminal contact spring by an auxiliary means.

3. The junction box according to claim 1, wherein the at least one terminal contact spring is formed resiliently such that when the applied force is missing, the at least one terminal contact spring fixes the electrical conductor arranged between the terminal contact spring and the terminal element and connects it with the contact device in an electrically conducting manner.

4. The junction box according to claim 1, wherein an opening area is assigned to each contact device, and wherein each contact device surrounds the assigned opening area.

5. The junction box according to claim 1, with four contact devices and four opening areas, wherein an opening area is assigned to each contact device, and each contact device surrounds the assigned opening area.

6. The junction box according to claim 1, wherein in a position of rest, the at least one terminal contact spring contacts the at least one terminal element at least partially in a mechanical manner.

7. The junction box according to claim 1, wherein if a force is applied along the direction of force, the at least one terminal contact spring is spaced from the at least one terminal element such that an insertion area is formed between the at least one terminal contact spring and the at least one terminal element.

8. The junction box according to claim 7, wherein the insertion area is arranged above the at least one opening area.

9. The junction box according to claim 1, wherein the at least one contact device is arranged relative to the at least one opening area such that the direction of force and the insertion direction are opposed.

10. The junction box according to claim 1, wherein the insertion area is designed such that the at least one electrical conductor is insertable into the insertion area through the opening area substantially free of force.

11. The junction box according to claim 1, wherein the terminal contact spring is a leaf spring.

12. The junction box according to claim 1, wherein
the terminal contact spring has a fixing area with which the terminal contact spring is fixed on the contact device, and
the terminal contact spring has an area that is proximal relative to the fixing area and an area that is distal relative to the fixing area, and wherein
the proximal area is designed such that when a force is applied to the proximal area parallel to the direction of force (K), the terminal contact spring de-contacts the terminal element, and when a force is applied to the distal area anti-parallel to the direction of force, the terminal contact spring contacts the terminal element.

13. The junction box according to claim 12, wherein in the proximal area, the terminal contact spring has a bend of approx. 10° to approx. 170°.

14. The junction box according to claim 1, wherein the contact element is formed in one piece.

15. A solar panel, according to claim 1, comprising:
at least one substantially plate-shaped solar module, and
at least one junction box wherein the solar module comprises at least two electrical conductors, and the at least two electrical conductors each project through an opening area of the junction box and are each connected with a contact device of the junction box.

16. A contact device for arrangement in a junction box, wherein
the contact device is arrangeable in the interior of the junction box such that at least one electrical conductor is insertable into the junction box through an opening area along an insertion direction and contactable with the at least one contact device, wherein
the contact device comprises at least one contact element with at least one resilient terminal contact spring and at least one terminal element, and wherein
by application of a force parallel to a direction of force relative to the terminal element, the terminal contact spring is resiliently displaceable such that the at least one electrical conductor is arrangeable at least partially between the at least one terminal element and the at least one terminal contact spring.

17. A method for automatically connecting a junction box with a conductor board, in particular a solar module, with the steps:
providing the junction box by means of a gripping means, wherein the junction box comprises at least one opening area and at least one contact device,
at least partially inserting an auxiliary means into the at least one contact device such that a terminal contact spring is resiliently displaced by means of the auxiliary means and an insertion area is formed in the contact device,
activating an adhesive on the junction box and/or on the conductor board,
arranging the junction box on a face of the conductor board such that at least one electrical conductor is inserted into the insertion area of the contact device through at least one opening area of the junction box, and the junction box is fixed on the conductor board by means of the adhesive,
removing the auxiliary means so that the terminal contact spring is returned at least partially and a connection between the contact device and the electrical conductor is established,
removing the gripping means.

18. The method according to claim 17, wherein the electrical conductor is fixed in the insertion area in the electrical contact device and connected with the electrical contact device in a conducting manner by means of the terminal contact spring.

19. The method according to claim 17, wherein the at least one electrical conductor is inserted into the insertion area of the contact device substantially free of force.

20. The method according to claim 17, wherein a cover device is arranged on the junction box such that the junction box is substantially fully closed.
